(19) United States
(12) Patent Application Publication
(10) Pub. No.: US 2026/0370200 A1
(43) Pub. Date: Nov. 19, 2026

(54) PEAKING STABILIZER FOR DIFFERENTIAL AMPLIFIERS USING A MULTI-GATE VARACTOR

(71) Applicant: MACOM Technology Solutions Holdings, Inc., Lowell, MA (US)

(72) Inventors: Duy NGUYEN, Lowell, MA (US); Abdelrahman H. AHMED, Lowell, MA (US); William ALLEN, Lowell, MA (US)

(21) Appl. No.: 19/210,028

(22) Filed: May 16, 2025

(51) Int. Cl. H03G 1/00; H03F 1/22; H03F 3/45

(52) U.S. Cl. CPC H03G 1/0023; H03F 1/22; H03F 3/4508; H03F 3/45475; H03F 2203/45256

(57) ABSTRACT

The present disclosure is generally directed to circuits, and in particular, to amplifier circuits and differential amplifiers. More specifically, the disclosure is directed to improving frequency response in differential amplifiers. In accordance with this exemplary new design, a multi-gate varactor us utilized to compensate for the peaking variation over a gain control range. The varactor is inserted between the two collectors of the differential amplifier. The gate of the varactor is controlled by a bias voltage which is proportional to the gain control voltage. The varactor's capacitance value changes as the gain control voltage changes. Thus, at a high gain, the varactor has a very low capacitance value. And at low gain, the capacitance value of the varactor is increased to adaptively reduce the peaking or CTLE variation of the frequency response of the amplifier stage.

### FIELD

The present disclosure is generally directed to circuits, and in particular, to amplifier circuits. More specifically, the disclosure is directed to improving differential amplifiers and/or cascode amplifiers. Even more specifically, the disclosure is directed to improving frequency response in amplifiers, differential amplifiers, cascode amplifiers, and the like.

### BACKGROUND

The background description includes information that may be useful in understanding the present inventive subject matter. It is not an admission that any of the information provided herein is prior art or relevant to the presently claimed disclosure, or that any publication specifically or implicitly referenced is prior art.

In electronics, an amplifier is an electronic device or circuit that increases the amplitude (or strength) of a signal. Amplification takes a small input signal and produces a larger output signal, often with a higher voltage, current, or power. The amount of amplification is measured by the amplifier's gain, which is the ratio of output power to input power. An amplifier is defined as having a power gain greater than one, meaning it amplifies the signal's power.

Amplifiers can be used in various applications, including: audio and music equipment (e.g., stereo systems, speakers), radio and communications systems, instrument amplifiers in scientific equipment, medical equipment, RF systems, and the like.

A differential amplifier amplifies the difference between two input signals while rejecting a common signal, often noise, interference, or the like, that is present in both inputs. The amplifier essentially extracts the unique, informative part of a signal while discarding the common noise present at both inputs.

Differential amplifiers are widely used in various applications, including, but not limited to: signal processing where weak signals in noisy environments are amplified, such as in audio circuits or sensors; sensor interfacing where signals from sensors are amplified that generate small voltage differences, like those in battery monitoring or temperature measurement; Analog-to-Digital Conversion (ADC) where analog signals are pre-processed before conversion to digital format; and control systems where a difference between a desired setpoint and a process variable is amplified.

A cascode amplifier is a two-stage amplifier configuration (typically using transistors) that improves bandwidth, input-output isolation, and output impedance compared to a single-stage amplifier. It is often used in radio frequency (RF) and other high-frequency applications.

A differential cascode amplifier combines the characteristics of a differential amplifier and a cascode amplifier. It is a single-stage amplifier with both differential inputs and outputs, often used in high-performance amplifier stages.

In general, frequency response of an amplifier describes how the amplifier's gain (amplification) changes as the input signal frequency changes. A flat frequency response means the gain is (substantially) constant across all (or substantially all) frequencies.

Gain peaking or “peaking” occurs when the gain of the amplifier does not stay constant but rather increases at a specific frequency(ies), creating a peak (or increase) in the frequency response.

Gain peaking, also known as Continuous-Time Linear Equalization (CTLE), can be used to compensate for loss in a system. Gain peaking occurs in the frequency domain, and can reduce peaking variations of changes in gain settings.

Additional information regarding CTLE can be found in US20200112462A1, entitled, CTLE Adaptation Based On Post-Cursors, which is incorporated herein by reference in its entirety.

In a differential amplifiers, peaking refers to a phenomenon where the gain of the amplifier increases at a specific frequency or range of frequencies in the frequency response, creating a noticeable peak.

### SUMMARY

Differential amplifiers are often used as the front end for Digital Signal Processors (DSPs) to improve noise and signal integrity. They offer the advantage of rejecting common-mode noise, which can be a significant problem in real-world signal acquisition.

For one conventional design, the peaking and frequency response changes significantly depending on the gain of the amplifier. At high gain, the peaking could be optimal but at low gain, the peaking could rise dramatically to an unacceptable level. This creates unwanted behavior for the system because the DSP is not able compensate for the different frequency responses. This large peaking variation degrades Bit Error Rate (BER) and Optical Signal-to-Noise Ratio (OSNR) of the system. For systems where differential amplifiers are used for the front end of a DSP, typically the design favors a low BER, and as high as possible OSNR.

In accordance with an exemplary new design, a multi-gate varactor is utilized to compensate for the peaking variation over the gain control range. The varactor is inserted between the two collectors of the differential bipolar transistors. The gate of the varactor is controlled by a bias voltage which is proportional to the gain control voltage. The varactor's capacitance value changes as the gain control voltage changes. Thus, at a high gain, the varactor has a very low capacitance value. And at low gain, the capacitance value of the varactor is increased to adaptively reduce the peaking of the frequency response.

The exemplary multi-gate topology can reduce the varactor size and parasitics, which makes it especially suitable for high frequency applications, although not limited thereto.

In accordance with one implementation, the peaking variation over gain was able to be reduced from 7.5 dB to 3 dB, and over 50% reduction.

Another exemplary benefit is that the varactor neither consumes any significant additional power nor has any substantial negative impacts on other specifications of the circuit such as gain, bandwidth, or linearity.

Another exemplary embodiment is especially useful for high frequency amplifiers (drivers and TIAs (transimpedance amplifiers)) with peaking or CTLE (Continuous Time Linear Equalization).

These and other exemplary advantages, techniques and designs will be described in greater detail herein.

The phrases “at least one,” “one or more,” and “and/or,” as used herein, are open-ended expressions that are both conjunctive and disjunctive in operation. For example, each of the expressions “at least one of A, B and C,” “at least one of A, B, or C,” “one or more of A, B, and ,” “one or more of A, B, or C” and “A, B, and/or C” means A alone, B alone, C alone, A and B together, A and C together, B and C together, or A, B and C together.

Unless otherwise indicated, all numbers expressing quantities, dimensions, conditions, and so forth used in the specification and claims are to be understood as being modified in all instances by the term “about.”

The use of “substantially” in the present disclosure, when referring to a measurable quantity (e.g., a diameter or other distance) and used for purposes of comparison, is intended to mean within 5% of the comparative quantity. The terms “substantially similar to,” “substantially the same as,” and “substantially equal to,” as used herein, should be interpreted as if explicitly reciting and encompassing the special case in which the items of comparison are “similar to,” “the same as” and “equal to,” respectively.

As used herein, unless otherwise specified, the terms “about,” “approximately,” etc., when used in relation to numerical limitations or ranges, mean that the recited limitation or range may vary by up to 10%. By way of non-limiting example, “about 750” can mean as little as 675 or as much as 825, or any value or fractional value therebetween. When used in relation to ratios or relationships between two or more numerical limitations or ranges, the terms “about,” “approximately,” etc., mean that each of the limitations or ranges may vary by up to 10%; by way of non-limiting example, a statement that two quantities are “approximately equal” can mean that a ratio between the two quantities is as little as 0.9:1.1 or as much as 1.1:0.9 (or any value therebetween), and a statement that a four-way ratio is “about 5:3:1:1” can mean that the first number in the ratio can be any value of at least 4.5 and no more than 5.5, the second number in the ratio can be any value of at least 2.7 and no more than 3.3, and so on.

The term “a” or “an” entity, as used herein, refers to one or more of that entity. As such, the terms “a” (or “an”), “one or more” and “at least one” can be used interchangeably herein.

The use of “including,” “comprising,” or “having” and variations thereof herein is meant to encompass the items listed thereafter and equivalents thereof as well as additional items. Accordingly, the terms “including,” “comprising,” or “having” and variations thereof can be used interchangeably herein. The use of “engaged with” and variations thereof herein is meant to encompass any direct or indirect connections between components.

It shall be understood that the term “means” as used herein shall be given its broadest possible interpretation in accordance with 35 U.S.C. § 112(f). Accordingly, a claim incorporating the term “means” shall cover all structures, materials, or acts set forth herein, and all of the equivalents thereof. Further, the structures, materials, or acts and the equivalents thereof shall include all those described in the summary, brief description of the drawings, detailed description, abstract, and claims themselves.

All external references are hereby incorporated by reference in their entirety whether explicitly stated or not.

These and other advantages will be apparent from this disclosure. The above-described embodiments, objectives, aspects and configurations are neither complete nor exhaustive. The Summary is neither intended nor should it be construed as being representative of the full extent and scope of the present disclosure. Moreover, references made herein to “the present disclosure,” or aspects thereof should be understood to mean certain embodiments of the present disclosure and should not necessarily be construed as limiting all embodiments to a particular description. The present disclosure is set forth in various levels of detail in the Summary as well as in the attached drawings and the Detailed Description and no limitation as to the scope of the present disclosure is intended by either the inclusion or non-inclusion of elements, components, etc. in this Summary. Additional aspects of the present disclosure will become more readily apparent from the Detailed Description, particularly when taken together with the drawings.

It is to be appreciated that any embodiment, feature, or aspect described herein can be claimed in combination with any other embodiment(s), feature(s), or aspect(s) as described herein, regardless of whether the features or aspects come from the same described embodiment. For example, any one or more aspects described herein can be combined with any other one or more aspects described herein. In addition, any one or more embodiment(s) or feature(s) described herein can be combined with any other one or more embodiment(s) or feature(s) described herein. Similarly, any one or more portions of the embodiment(s) or feature(s) described herein can be combined with any other one or more portions of the embodiment(s) or feature(s) described herein.

### BRIEF DESCRIPTION OF THE DRAWINGS

Those of skill in the art will recognize that the following description is merely illustrative of the principles of the disclosure, which may be applied in various ways to provide many different alternative embodiments. This description is made to illustrate the general principles of the teachings of this disclosure and is not meant to limit the inventive concepts disclosed herein.

The accompanying drawings, which are incorporated in and constitute a part of the specification, illustrate embodiments and together with the general description of the disclosure given above and the detailed description of the drawings given below, serve to explain the principles of the disclosure.

FIG. 1 illustrates a schematic of a cascode amplifying stage.

FIG. 2 illustrates an exemplary simplified schematic of a cascode stage including the circuit equivalent varactor according to one exemplary embodiment.

FIG. 3 illustrates a schematic of one exemplary embodiment of a peaking stabilizer circuit in a cascode stage according to one exemplary embodiment.

FIG. 4 illustrates a chart of the varactor capacitance (y-axis) relative to the gain control voltage.

FIG. 5 illustrates an exemplary comparison of frequency response (gain and normalized gain) of a conventional (shown in dashed line) circuit configuration and that of the improved design disclosed herein (solid line) at different frequencies (x-axis).

It should be understood that the drawings are not necessarily to scale, and various dimensions may be altered. In certain instances, details that are not necessary for an understanding of the disclosure or that render other details difficult to perceive may have been omitted. It should be understood, of course, that the disclosure is not necessarily limited to the particular embodiments illustrated herein.

### DETAILED DESCRIPTION

Although the following text sets forth a detailed description of numerous different embodiments, it should be understood that the legal scope of the description is defined by the words of the claims set forth at the end of this disclosure. The Detailed Description is to be construed as exemplary only and does not describe every possible embodiment since describing every possible embodiment would be impractical, if not impossible. Numerous alternative embodiments could be implemented, using either current technology or technology developed after the filing date of this patent, which would still fall within the scope of the claims. Additionally, any combination of features shown in the various figures can be used to create additional embodiments of the present disclosure. Thus, dimensions, aspects, and features of one embodiment can be combined with dimensions, aspects, and features of another embodiment to create the claimed embodiment.

It is with respect to the above-noted challenges that embodiments of the present disclosure were contemplated. In particular, a system, circuits, and method of designing and providing such circuits are provided that solve the drawbacks associated with existing amplifier circuits, driver circuits, equalizer circuits or in general at least any circuit that has an amplifier.

While embodiments of the present disclosure will primarily be described in connection with amplifier circuits used in high-bandwidth applications, it should be appreciated that embodiments of the present disclosure are not so limited. Furthermore, while embodiments of the present disclosure are contemplated for use in connection with high-speed communications amplifiers for copper or fiber, it should be appreciated that the claims are not limited to high speed electrical and optical or electro-optical communications technologies. Indeed, the biasing configuration(s) depicted and described herein may be utilized in any number of applications or in general on any circuit or similar and can be especially useful in circuits utilizing an amplifier (e.g., transmitter applications, receiver applications, filtering applications, etc.) such as a differential amplifier, and even more specifically to a cascode differential amplifier that provides input to a DSP. Example embodiments of the present disclosure will be described in connection with broadband applications, but it should be appreciated that the circuit(s) depicted and described herein can be utilized in other non-broadband applications.

Various aspects of the present disclosure will be described herein with reference to drawings that are schematic illustrations of idealized configurations. It should be appreciated that while particular circuit configurations and circuit elements are described herein, embodiments of the present disclosure are not limited to the illustrative circuit configurations and/or circuit elements depicted and described herein. Specifically, it should be appreciated that circuit elements of a particular type or function may be replaced with one or multiple other circuit elements to achieve a similar function without departing from the scope of the present disclosure.

It should also be appreciated that the embodiments described herein may be implemented in any number of form factors. Specifically, the entirety of the circuits disclosed herein may be implemented in silicon as a fully-integrated solution (e.g., as a single Integrated Circuit (IC) chip or multiple IC chips) or they may be implemented as discrete components connected to a Printed Circuit Board (PCB). For example, circuit components depicted and described herein may be provided on a single piece of silicon (e.g., a single semiconductor die), on multiple pieces of silicon, on a PCB, or combinations thereof.

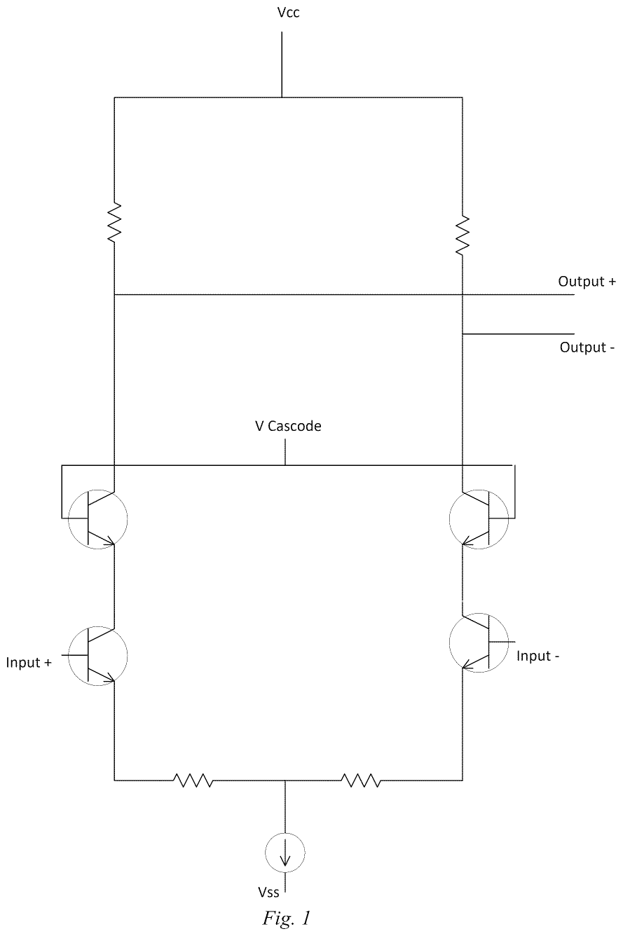

FIG. 1 illustrates in block diagram form, a simplified schematic of a cascode stage amplifier. The amplifier circuit includes a plurality of transistors with two inputs, Input+and Input−. As discussed, this amplifier amplifies a difference between the two input signals while rejecting a common signal, often noise, interference, or the like, present in both inputs. This amplified output is then output as a positive output (Output+) and a negative output (Output−).

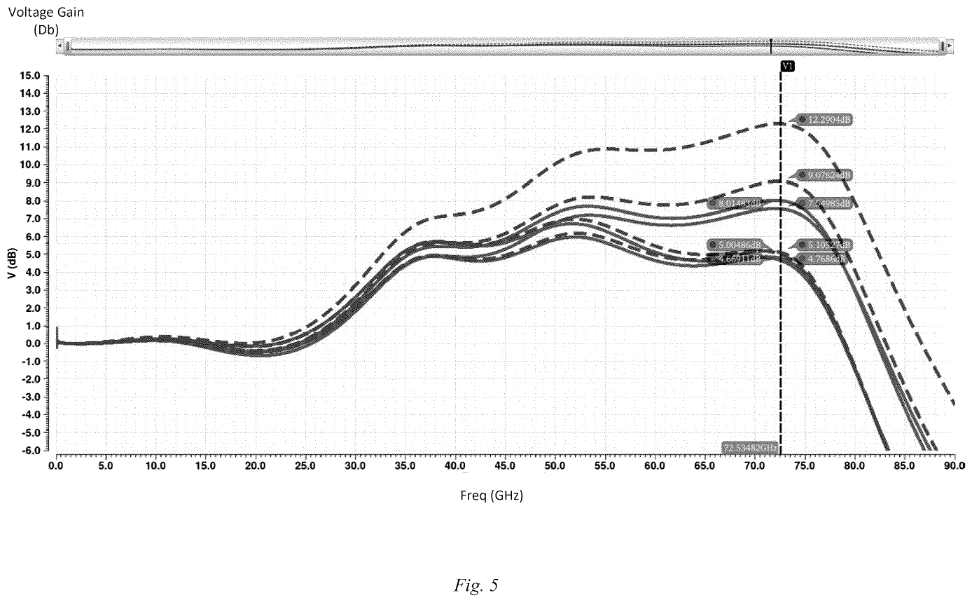

This type of circuit suffers from the exact issues discussed above, i.e. peaking variation (See conventional plot in FIG. 5)

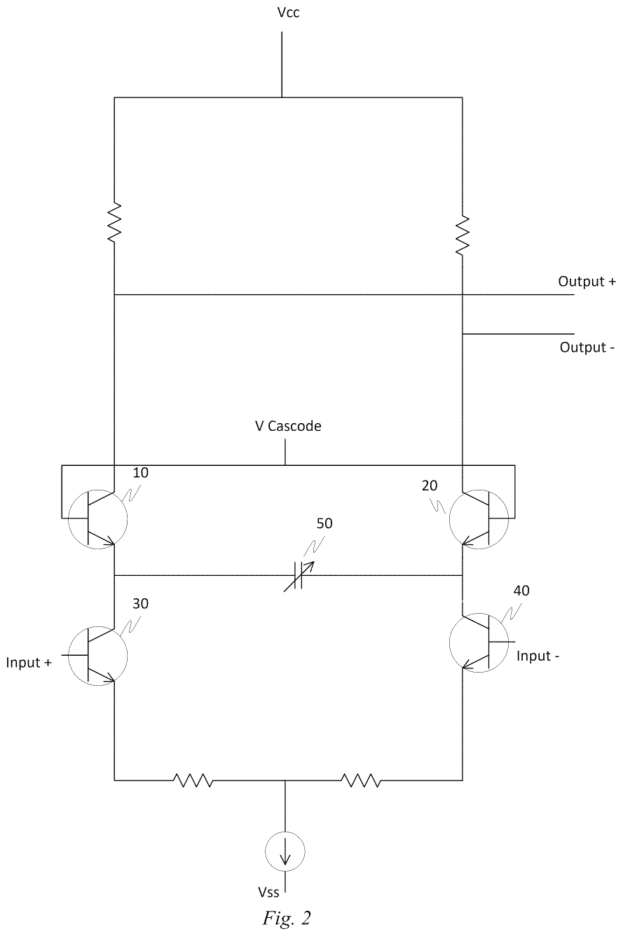

FIG. 2 illustrates an exemplary simplified schematic of a cascode amplifier design including the circuit equivalent varactor according to one exemplary embodiment. As varactors are capacitors in which the capacitance value changes based on a bias voltage, the schematic has been simplified to represent the varactor 50 as a variable capacitor. In this exemplary design, the varactor has been placed on the collector side of transistors 30 and 40. While other locations for the placement of varactor 50 are possible, this configuration was very effective at addressing peaking variation as discussed hereinafter. Since capacitors have a larger effect on high frequency signals, and behave as essentially an open circuit at lower frequencies, this circuit configuration is particularly useful in higher frequency applications, such as RF applications, in the 20+ GHz frequency range.

Non-exhaustive types of transistors that can be used with the exemplary circuit include, but are not limited to: FETs, bipolar junction transistors (BJT), HBT, JFETs, MOSFETs, IGBTs, and the like.

In addition, it has been discovered that utilizing a multi-gate design for the varactor can reduce or minimize the layout size. This can be particularly advantageous in amplifier designs for RF applications where space can be tightly constrained.

The varactor's capacitance can be changed by applying a reverse bias voltage thereto. This reverse bias voltage controls the width of the depletion region within the diode, which in turn affects the capacitance. Varactors are typically operated in reverse bias, where the applied voltage causes the junction to widen and the capacitance to decrease. Because of this, the simplified circuit in FIG. 2 should be supplemented with an operational amplifier. This operational amplifier is configured to provide the appropriate reverse bias voltage to the varactor such that it is operated in within its operational constraints. In one exemplary configuration, the operational amplifier is designed to scale the input to the system to that of the operational range of the varactor.

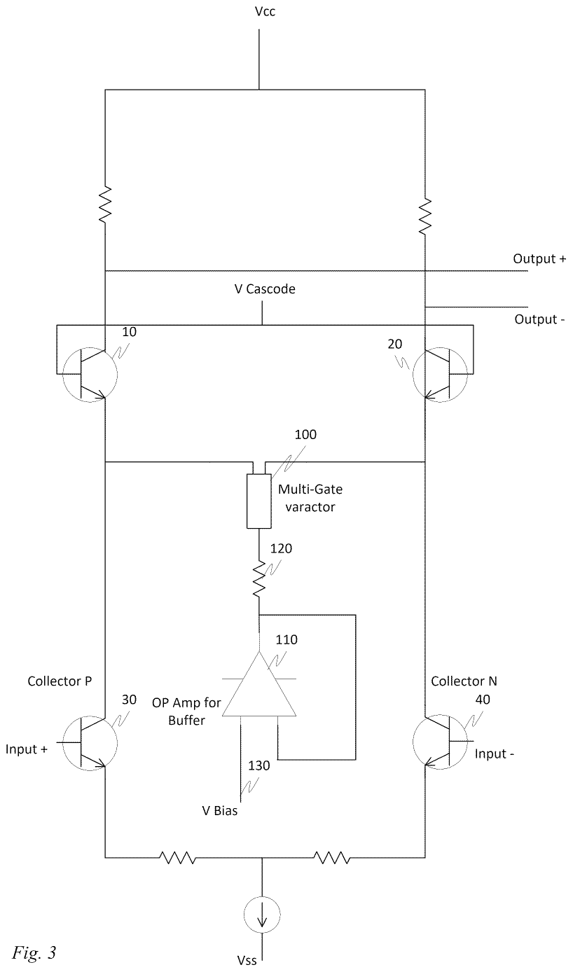

FIG. 3 illustrates a schematic of one exemplary embodiment of a peaking stabilizer circuit according to one exemplary embodiment. This exemplary embodiment includes the operational amplifier 110, the multi-gate varactor 100 (connected to the collector-side of transistors 30 and 40, respectively, bias resistor 120 and the bias voltage input 130. This exemplary embodiment is only a partial view of the core components for one gain stage of several stages of a differential amplifier, and in particular a cascode differential amplifier. It is to be appreciated that additional components couple be included in the circuit depending on the specific implementation.

The operational amplifier 110 adjusts the operating voltage that is the input for the circuit (V bias) from an input value to a value constrained by the operating parameters of the varactor. This ensures that the varactor operates within its design parameters. So for example, if the input from the amplifier varies from 0V to 2.5V, the operational amplifier can be configured to vary the bias voltage to drive the varactor 100 to between 0.5V and 2.0V.

The optional bias resistor 120 provides isolation for the varactor 100.

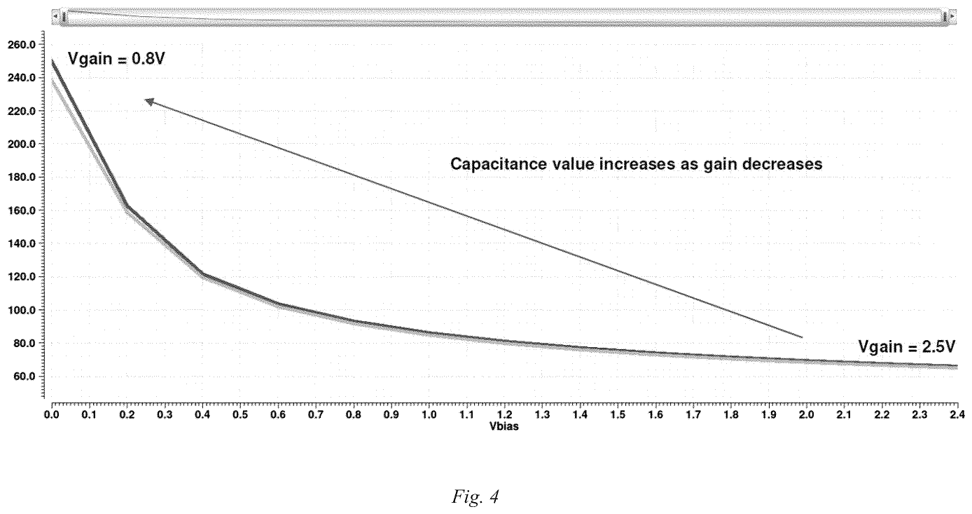

FIG. 4 illustrates a chart of the varactor capacitance (y-axis—capacitance value in femto farad—f) relative to the gain voltage (x-axis—voltage value in V). Capacitance can be seen as increasing in value as gain control voltage decreases. In this illustrative example, gain control voltage varies from 0.8V to 2.5V, with capacitance varying as shown in the chart. This relationship can be used as input to control the varactor and thus the high frequency peaking or CTLE.

FIG. 5 illustrates an exemplary comparison of frequency response (gain and normalized gain) of a conventional (shown in dashed line) circuit configuration and that of the improved design disclosed herein (solid line) at different frequencies (x-axis). This chart particularly illustrates a normalized frequency response and the peaking present for the prior design relative to the new circuit design disclosed herein. In the prior design, peaking at the variation of gain voltages shown varied by a little over about 7 dB. For the improved design, peaking variation was reduced for the same input voltages to just about 3.5 dB. With the desire to have peaking as consistent as possible such that the DSP can appropriately compensate, this technique shows a marked improvement over the prior circuit design.

While exemplary embodiments are shown for illustrative purposes, it is to be appreciated that the varactor disclosed herein is not so limited and variations and modifications can occur. For example, other types of transistors could be employed, such as FETs, with comparable success.

Additionally, the techniques disclosed herein can be applied and replicated, for example, when the differential amplifier is one stage of a multi-stage differential amplifier, a varactor and operational amplifier can be installed in one or more of (or each) additional stages of the multi-stage differential amplifier.

This technique can be used for any type of amplifier including single-ended amplifiers, differential amplifiers, cascode stage amplifiers, common emitter/common base amplifier, or the like. The transistor devices can be FETs, BJTs, HBTs, JFETs, MOSFETs, IGBTs, or the like. Moreover, the varactor can be placed in one or multiple stages in a multi-stage amplifier design.

Exemplary aspects are directed toward:
An electronic device comprising:
a differential amplifier including:
a first transistor with a collector leg;
a second transistor with a collector leg;
a varactor connected between the collector leg of the first transistor and the collector leg of the second transistor; and
a circuit configured to vary a bias voltage of the varactor, and thus the capacitance thereof, to reduce peaking variation of the differential amplifier.

Any of the above aspects, wherein the circuit comprises an operational amplifier configured to receive an input voltage.

Any of the above aspects, wherein the circuit further comprises at least one bias resistor configured to provide isolation for the varactor.

Any of the above aspects, wherein the circuit is configured to modify an input voltage to an operating voltage of the varactor.

Any of the above aspects, wherein the varactor is a multi-gate varactor.

Any of the above aspects, wherein the device is configured for use in RF circuits operating in the GHz range.

Any of the above aspects, wherein the differential amplifier is one stage of a multi-stage differential amplifier.

Any of the above aspects, wherein another varactor and another circuit is present in one or more of additional stages of the multi-stage differential amplifier.

Any of the above aspects, wherein the device is connected to and is configured to provide input to a DSP.

Any of the above aspects, further comprising a plurality of input nodes and a plurality of output nodes.

Any of the above aspects, wherein the circuit comprises an operational amplifier configured to receive an input voltage of the differential amplifier on a first node, and output a normalized version of the input voltage on another node.

Any of the above aspects, wherein the varactor is configured such that a capacitance value thereon increases as gain of the differential amplifier decreases.

Any of the above aspects, wherein the device is operational in the 5-200 GHz range.

Any of the above aspects, wherein peaking variation is reduced by approximately at least 50%.

An electronic circuit comprising:
a differential amplifier including:
a first transistor with a collector leg;
a second transistor with a collector leg;
a multi-gate varactor, wherein a first gate is connected to the collector leg of the first transistor and a second gate is connected to the collector leg of the second transistor;
a resistor connected to a third gate of the multi-gate varactor; and
an operational amplifier circuit connected to the resistor and configured to vary a bias voltage of the varactor, and thus the capacitance thereof, to reduce peaking variation of the differential amplifier.

Any of the above aspects, wherein the operational amplifier circuit is configured to receive an input voltage of the differential amplifier.

Any of the above aspects, wherein the operational amplifier circuit is configured to modify the input voltage of the differential amplifier to be proportionally adjusted to an operating voltage of the varactor.

Any of the above aspects, wherein the device is connected to and is configured to provide input to a DSP.

Any of the above aspects, wherein the circuit is present in a plurality of stages of a multi-stage amplifier.

An electronic circuit comprising:
a differential amplifier including:
a first transistor with a collector leg;
a second transistor with a collector leg;
a varactor connected between the collector leg of the first transistor and the collector leg of the second transistor; and
means for varying a bias voltage of the varactor, and thus the capacitance thereof, to reduce peaking or CTLE variation of the differential amplifier.

Any one or more of the above aspects/embodiments as substantially disclosed herein.

Any one or more of the aspects/embodiments as substantially disclosed herein optionally in combination with any one or more other aspects/embodiments as substantially disclosed herein.

One or means adapted to perform any one or more of the above aspects/embodiments as substantially disclosed herein.

Any one or more of the features disclosed herein.

Any one or more of the features as substantially disclosed herein.

Any one or more of the features as substantially disclosed herein in combination with any one or more other features as substantially disclosed herein.

Any one of the aspects/features/embodiments in combination with any one or more other aspects/features/embodiments.

Use of any one or more of the aspects or features as disclosed herein.

While various embodiments of the present disclosure have been described in detail, it is apparent that modifications and alterations of those embodiments will occur to those skilled in the art. However, it is to be understood that such modifications and alterations are within the scope and spirit of the present disclosure, as set forth in the following claims. Further, the disclosure described herein is capable of other embodiments and of being practiced or of being carried out in various ways. It is to be understood that the phraseology and terminology used herein is for the purpose of description and should not be regarded as limiting.

1. An electronic device comprising:
a differential amplifier including:
a first transistor with a collector leg;
a second transistor with a collector leg;
a varactor connected between the collector leg of the first transistor and the collector leg of the second transistor; and
a circuit configured to vary a bias voltage of the varactor, and thus the capacitance thereof, to reduce peaking variation of the differential amplifier.

2. The device of claim 1, wherein the circuit comprises an operational amplifier configured to receive an input voltage.

3. The device of claim 2, wherein the circuit further comprises at least one bias resistor configured to provide isolation for the varactor.

4. The device of claim 2, wherein the circuit is configured to modify an input voltage to an operating voltage of the varactor.

5. The device of claim 1, wherein the varactor is a multi-gate varactor.

6. The device of claim 1, wherein the device is configured for use in RF circuits operating in the GHz range.

7. The device of claim 1, wherein the differential amplifier is one stage of a multi-stage differential amplifier.

8. The device of claim 7, wherein another varactor and another circuit is present in one or more of additional stages of the multi-stage differential amplifier.

9. The device of claim 1, wherein the device is connected to and is configured to provide input to a DSP.

10. The device of claim 1, further comprising a plurality of input nodes and a plurality of output nodes.

11. The device of claim 1, wherein the circuit comprises an operational amplifier configured to receive an input voltage of the differential amplifier on a first node, and output a normalized version of the input voltage on another node.

12. The device of claim 1, wherein the varactor is configured such that a capacitance value thereon increases as gain of the differential amplifier decreases.

13. The device of claim 1, wherein the device is operational in the 5-200 GHz range.

14. The device of claim 1, wherein peaking variation is reduced by approximately at least 50%.

15. An electronic circuit comprising:
a differential amplifier including:
a first transistor with a collector leg;
a second transistor with a collector leg;
a multi-gate varactor, wherein a first gate is connected to the collector leg of the first transistor and a second gate is connected to the collector leg of the second transistor;
a resistor connected to a third gate of the multi-gate varactor; and
an operational amplifier circuit connected to the resistor and configured to vary a bias voltage of the varactor, and thus the capacitance thereof, to reduce peaking variation of the differential amplifier.

16. The circuit of claim 15, wherein the operational amplifier circuit is configured to receive an input voltage of the differential amplifier.

17. The circuit of claim 15, wherein the operational amplifier circuit is configured to modify the input voltage of the differential amplifier to be proportionally adjusted to an operating voltage of the varactor.

18. The circuit of claim 15, wherein the device is connected to and is configured to provide input to a DSP.

19. The circuit of claim 15, wherein the circuit is present in a plurality of stages of a multi-stage amplifier.

20. An electronic circuit comprising:
a differential amplifier including:
a first transistor with a collector leg;
a second transistor with a collector leg;
a varactor connected between the collector leg of the first transistor and the collector leg of the second transistor; and
means for varying a bias voltage of the varactor, and thus the capacitance thereof, to reduce peaking or CTLE variation of the differential amplifier.
